(19) United States
(12) Patent Application Publication
(10) Pub. No.: US 2022/0254660 A1
(43) Pub. Date: Aug. 11, 2022

(54) SUBSTRATE PROCESSING APPARATUS

(71) Applicant: LINCO TECHNOLOGY CO., LTD., Taichung (TW)

(72) Inventors: YI-YUAN HUANG, Taichung (TW); YI-CHENG LIU, Taichung (TW)

(21) Appl. No.: 17/168,206

(22) Filed: Feb. 5, 2021

(51) Int. Cl. H01L 21/67; H01L 21/3065; H01J 37/305; H01J 37/32

(52) U.S. Cl. CPC H01L 21/67069; H01J 37/32513; H01J 37/3053; H01L 21/3065

(57) ABSTRACT

A substrate processing apparatus, comprising: a processing chamber having a plasma intake wall configured to receive plasma from a remote plasma source (RPS) and a surrounding wall having inner surface defining an interior volume for receiving a substrate; and a substrate support having a substrate supporting surface facing the plasma intake wall and elevatably arranged in the interior volume of the processing chamber. The surrounding wall, in a cross-section of the processing chamber, includes: a first segment having a first width associated with a processing region for the substrate support; a second segment having a width greater than the first width that is further away from the plasma intake wall than the first segment.

### FIELD

The present disclosure relates to processing equipment, and in particular to substrate processing equipment that incorporates remote plasma source (RPS).

### BACKGROUND

The International Technology Roadmap for Semiconductors (ITRS) pointed out that the traditional CMOS process is close to its limit. In response to the continuous growth of industry and the reduction of the cost per unit function, new device types, new packaging architecture, and new materials are required. Particularly, as Moore's Law approaches its end, the development of the semiconductor industry may switch focus to heterogeneous integration. As a result, system in package (SiP) technology would become a critical solution that balances both performance diversity and cost. In response to this new architecture, embedded devices that include printed circuits, thinner wafers, and active/passive may be vigorously developed. The fabrication tools/equipment and process materials used in advanced packaging may also undergo rapid changes to meet the demand of the new architecture. In the next 15 years, the focus of heterogeneous integration may be placed on assembly, packaging, testing, and interconnection technologies.

Advanced packaging technology such as embedded die in substrate (EDS), embedded passive in substrate (EPS), and fan-out panel level package (FOPLP) often calls for the use of composite substrate having dielectric insulating materials, semiconductor element chips, and metal wirings embedded therein. In some fabrication processes where EDS, EPS, or FOPLP packaging techniques are applied, the singulated semiconductor components, passive components or metal bump (e.g., copper pillar) are arranged and buried in a large organic insulating material (such as molding compound, Copper Clad Laminate (CCL), Ajinomoto Build-up Film (ABF), or dry film photoresist); then unnecessary organic insulating material is thinned by grinding to selectively expose chip components or metal wires. However, during the grinding process, the chip or component may be damaged by external stress.

### BRIEF DESCRIPTION OF DRAWINGS

The invention can be more fully understood by reading the following detailed description of the embodiment, with reference made to the accompanying drawings as follows:

FIG. 1 shows a schematic cross-sectional view of a substrate processing equipment according to some embodiments of the present disclosure;

FIG. 2 shows an enlarged regional view of a substrate manufacturing equipment according to some embodiments of the present disclosure;

FIG. 3A shows an isometric exploded illustration of components for a substrate manufacturing equipment according to some embodiments of the present disclosure;

FIGS. 3B and 3C respectively shows a three-dimensional schematic diagram of a substrate support according to some embodiments of the present disclosure;

FIG. 4 shows a schematic illustration of a bottom face of a plasma inlet wall according to some embodiments of the present disclosure;

FIG. 5 shows a schematic cross-sectional view of a plasma inlet wall according to some embodiments of the present disclosure;

FIG. 6 shows a schematic regional cross-sectional view of a plasma inlet wall according to some embodiments of the present disclosure;

FIG. 7 shows experimental test data of a substrate processing equipment in accordance with some embodiments of the present disclosure; and

FIG. 8 shows a schematic top view of a substrate processing equipment according to some embodiments of the present disclosure.

It is to be noted, however, that the appended drawings illustrate only exemplary embodiments of this disclosure and are therefore not to be considered limiting of its scope, for the disclosure may admit to other equally effective embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of layers, regions and/or structural elements may be reduced or exaggerated for clarity. The use of similar or identical reference numbers in the various drawings is intended to indicate the presence of a similar or identical element or feature.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

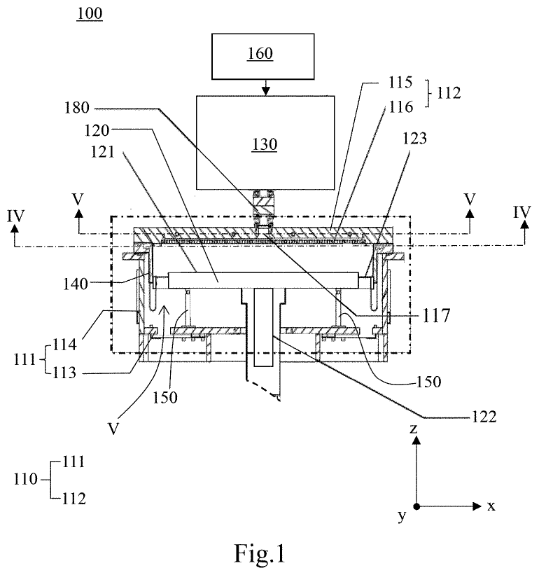

Exemplary embodiments will be described in conjunction with the drawings from FIGS. 1 to 8. The present disclosure will be described in detail with reference to the accompanying drawings, in which the depicted elements are not necessarily shown to scale, and through several views, the same or similar reference signs may be used to denote the same or similar elements.

FIG. 1 shows a schematic cross-sectional view of a substrate manufacturing apparatus according to some embodiments of the present disclosure. For simplicity and clarity of description, some details/sub-components of the exemplary system are not clearly marked/shown in this figure.

The substrate processing equipment 100 can be operated to perform many processes that apply plasma, e.g., using plasma to etch and/or thin down dielectric insulating materials. Take EDS, EPS, or FOPLP packaging applications for example, some applications call for the thinning of dielectric insulating materials (such as Epoxy Molding Compound (EMC) and ABF (Ajinomoto Build-up Film, ABF) insulating film) to achieve, e.g., surface flattening/planarization and/or die exposure. In addition to the above-mentioned thinning process of insulating materials, the substrate processing equipment 100 may also be utilized for, e.g., removal of surface organic or inorganic residues, ashing process, photoresist stripping, hydrophilic and hydrophobic surface treatment processes (such as modification and surface cleaning), descum or desmear removal, etching treatment after laser treatment, ashing treatment of photoresist, etching treatment of titanium film, SiO₂ film or Si₃N₄ film metal oxide film plasma reduction treatment.

The exemplary substrate processing equipment 100 includes a processing chamber 110, a substrate stage/carrier 120, and a remote plasma source (RPS) 130. The processing chamber 110 defines an internal space V configured to receive a processing workpiece (now shown in the instant illustration). In some embodiments, the processing workpiece may be a substantially planar object generally referred to as a substrate, which provides mechanical support to subsequently formed electrical components formed thereon. In some applications, the substrate may be a semiconductor wafer. In some applications, e.g., panel level processes such as FOPLP packaging applications or advanced IC board with thin circuit traces, the substrate may include large size glass substrate, epoxy molding compound, copper clad laminate, or coreless substrate. The exemplary processing chamber 110 includes a base 111 and a plasma inlet wall 112. The base 111 has a bottom wall 113 and a side wall 114 to define an internal space V. The plasma inlet wall 112 is configured to cooperatively establish a closure with the base and receive output from the remote plasma source 130. In some embodiments, the output from the remote plasma source 130 may be free radicals that are electrically neutral. In some embodiments, the substrate processing equipment 100 further includes a baffle ring 140 The baffle ring 140 is arranged to situate between the base 111 and the plasma inlet wall 112.

The substrate carrier/stage 120 is elevatably arranged in the internal space V of the process chamber 110 and has a substrate supporting surface 121 facing the plasma inlet wall 112. The substrate carrier 120 (e.g., pedestal) is configured to support the substrate on a top surface thereof (e.g., the substrate supporting surface 121) during the manufacturing process. In some embodiments, the apparatus 100 further includes one or more lifting devices coupled to the substrate stage 120, and the lifting devices are adapted to move the substrate stage 120 at least in a vertical direction (for example, the z-direction) to facilitate substrate loading/unloading operations, and/or to adjust a distance between the substrate and the plasma inlet wall 112 (the nozzle member). When the substrate carrier 120 is lowered, the lifting pin 150, provided in a lower portion of the process chamber 110, can extend upward to support the substrate to facilitate loading/extraction operation of the workpiece into/out of the chamber. In some embodiments, the substrate carrier 120 is further provided an exhaust mechanism (e.g., gas extraction/exhaust channel 123). As illustrated in the instant embodiment, the exhaust channel 123 is arranged proximate the outer edge region of the carrier 120, while the lateral edge(s) of the carrier is maintained at a close proximity from a corresponding section (e.g., the upper half portion) of the inner chamber surface. When an exhaust/extracting device (not shown in the figure) is activated, the by-products (often in micro-particle or gaseous form) can be moved to the space below the substrate carrier 120 through the exhaust channel 123. In some embodiments, the stage is further provided with a positioning ring (or cover ring) arranged around the substrate supporting surface 121 and is located between the substrate supporting surface 121 and the exhaust channel 123. In some embodiments, the positioning ring comprises an insulating material, such as Al₂O₃, ZrO₂, Si₃N₄, AlN, machinable ceramics, Quartz, glass, or Teflon.

The plasma intake wall 112 is configured to close the trough-like structure of the base 111, thereby establishing a sealing engagement to form the internal space V of the process chamber 110. The plasma intake wall 112 is in fluid communication with the remote plasma source 130 through intake port 117 over a central region of the carrier 120, so the outputs from the remote plasma source 130 may be directed and distributed into the chamber 110. In the illustrated embodiment, the plasma intake wall 112 includes a cover 115 and a plasma distribution member 116 disposed between the inlet port 117 and the substrate supporting surface 121. The outer periphery of the cover 115 (or referred to as a chamber cover) is configured to establish sealing engagement with the top of the surrounding wall of the base 111. The plasma distribution component 116 (e.g., spray head component/spray head) is configured to uniformly supply output/processing gas from the remote plasma source 130 into the process volume 111. The shower head component is shown to be arranged in a substantially parallel relationship with respect to the carrying surface of the substrate stage 120, which facilitates the uniform distribution of processing gas over a workpiece. Nevertheless, the distribution state of processing gas is affected by various factors, such as the geometric structure of the internal space V, the distance between the plasma distribution component 116 and the substrate stage 120. In some embodiments, the distance between the plasma distribution component 116 and the substrate stage 120 is substantially in a range of 10-200 mm, such as 30 or 90 mm. In some embodiments, the plasma distribution component 116 and the cover 115 may be made of conductive materials (such as aluminum) and be in electrical communication with each other. The base 111 can also be electrically connected to the plasma distribution component 116 and the cover 115 by using a conductive material (such as aluminum).

The substrate processing equipment 100 may also include, or otherwise in connection with, an exhaust/exhaust system (not shown), which is configured to apply a negative pressure to the internal space V (or the process volume) to generate vacuum condition. In some applications, the operating pressure in the chamber may be controlled at about 50-5000 mTorr.

In some applications, the utilization of RPS may allow most of the generated charged particles (e.g., ions and electrons) from the plasma generator to be kept from the process chamber (such as the internal space V), while granting passage of the electrically neutral free radicals into the processing chamber through the inlet component (such as the plasma intake wall 112). The use of free radical may enable lowered processing temperature for certain delicate applications. In some applications, when the gas from gas source 160 reaches sufficient gas flow rate (e.g., several standard liters per minute (SLM), the dissociation rate of the remote plasma source for the process gas may reach 95% or more. Thus, in some embodiments, the remote plasma source may also be referred to as a free radical plasma source. For instance, in plasma etching processes, the etching rate over the workpiece is proportional to the density of free radicals in the process chamber. Because the free radicals generated by the remote plasma source predominately induce chemical reaction over the surface of the substrate, the resulting lowered thermal loading and reduced ion bombardment by using RPS may help to minimize physical damage to the workpiece in a various of applications such as high-speed etching, ashing, desmearing, descum, cleaning, or surface modification/activation treatment operations.

The remote plasma source is configured to receive various gases (for example, from the gas source 160), such as fluorine-containing reactant gas (such as CF₄, CxFy, SF₆, NF₃, CHF₃ or their mixed gas) and cleaning gas (such as O₂, O₃, H₂O, H₂, He, N₂, Ar or their mixed gas). The addition of N₂ gas may increase plasma density and prolong the lifetime of output gas in free radical form. The gas source 160 may provide the gas at a controlled flow rate. For instance, when the fluorine-containing gas is provided to the remote plasma source, the flow rate may be regulated to be within about 10 to 6000 sccm. For example, in various embodiments, the fluorine-based gas may be provided at a flow rate between about 10 to 3000 sccm, between about 10 to 2000 sccm, or between about 10 to 1000 sccm. Likewise, when the cleaning gas is supplied to the RPS, the flow rate may be controlled between about 10-6000 sccm. For example, in various embodiments, the flow rate of the cleaning gas may be regulated between about 10 to 5000 sccm, about 10 to 4000 sccm, about 10 to 3000 sccm, about 10 to 2000 sccm, or about 10 to 1000 sccm.

The remote plasma source may adopt inductively-coupled plasma source (ICP), capacitively coupled (CCP) remote plasma source, and a microwave remote plasma source (Microwave RPS), or a combination thereof. In an embodiment wherein an inductively coupled remote plasma source (ICP RPS) is used, the driving frequency thereof may be set to about 0.4 to 13.56 MHz. In an embodiment using a very high frequency (VHF) capacitive coupling type remote plasma source, the driving frequency be set to about 40 to 100 MHz. In an embodiment where a microwave remote plasma source (Microwave RPS) is used, the driving frequency may be set to about 900 to 6000 MHz Hz. In various embodiments that incorporate RPS, the output power may be in the range of about 1-3 kW, 1-6 kW, 1-8 kW, 1-10 kW, or 1-15 kW.

In some operating scenarios, the free radicals from the RPS will generate a recombination reaction (exothermic reaction) in the pipeline (e.g., the passage between to the RPS and the plasma inlet) so as to cause elevation of temperature in the pipeline. In some cases, the elevation of temperature is pronounced and may cause excessive wear of the device hardware (e.g., O-ring). In some embodiments, the exemplary device in accordance with the instant disclosure is provided with a cooling mechanism 180. The cooling mechanism may include a liquid-cooled flow channel configured to receive cryogenic fluid (for example, water, other liquids or gases) from a fluid supply system. In some embodiments, the processing equipment further comprises a valve configured to regulate fluid communication from the RPS to the processing chamber 110. In some embodiments, the cooling mechanism 180 may further include a cooling chip (e.g., thermoelectric cooling module) in thermal contact with the valve body.

In some embodiments, in addition to the first plasma generating device (which includes the remote plasma source 130), the apparatus 100 may also be provided with a second plasma generating device (e.g., a local/onboard plasma generator) provided in the process chamber. In terms of hardware configuration, in some embodiments, the substrate stage 120 may be configured to be coupled to electrode member 122 that receives output from a radio frequency (RF) power source. Meanwhile, the shower head component (e.g., the plasma distribution component 116) may be configured to be electrically connected (e.g., to the ground), so that the shower head and the substrate stage 120 respectively form a pair of opposite electrodes for the onboard/local plasma generator.

In an embodiment of dual plasma source configuration, the remote plasma source may employ one or more of inductively coupled remote plasma source (ICP RPS), capacitively coupled remote plasma source (CCP RPS), and microwave remote plasma source (Microwave RPS). On the other hand, the aforementioned radio frequency plasma source (i.e., the second plasma source) may adopt a capacitive coupling device. The plasma generator incorporated devices may be used to perform material reduction processes such as Reactive-Ion Etching (RIE). Exemplary applications of RIE may include ashing process, photoresist stripping, surfaces modification, cleaning and activation, descum, desmear, nitrogen/argon based plasma treatment for copper film to remove surface oxides/fluorides, or for surface roughening applications. In the illustrated embodiment, when RPS (first plasma generator) generates high-density reactive free radicals, high-frequency bias may be concurrently applied to the substrate stage (second plasma generator). With the help of physical and chemical etching, the rate of etching or plasma processing may be greatly improved. Generally speaking, for equipment that possesses only RF plasma source, the plasma density and ion bombardment energy are often not simultaneously adjustable. By increasing the RF power, the plasma density and the dissociation rate of the process gas can be increases, thereby enhancing the etching rate. However, high RF power setting may cause excessively large bombardment energy. As a result, the substrate material may be damaged due to excessive temperature or arc discharge. On the other hand, to prevent damage from excessive temperature, the range of the RF power setting may be restricted. However, the etching rate (e.g., when etching an insulating dielectric organic substrate such as epoxy resin molding compound or ABF build-up material) would be limited in a range from about 0.5 to 1 um/min as a result.

In contrast, the incorporation of a remote plasma source may boost the etching rate by 100% to 400%. For instance, compared with tools that possess only the onboard radio frequency sources, the application of remote plasma generation equipment allows the ion bombardment energy to be adjusted (e.g., from zero ion bombardment to hundreds of volts bias). As such, the process temperature may be reduced. Take packaging process for example, the application of RPS may help to maintain the temperature of the stage to no more than 100 Celsius degree. In some scenarios, the operating temperature is maintained under 50 Celsius degree. In some scenarios, the operating temperature is less than 30 Celsius degree.

With the demand for electrical compounds miniaturization, high frequency/switching speed, 5G substrate material, and micro circuit technology, there is a need for process temperature control due to the delicacy of advanced materials and the demand for high plasma uniformity over increased substrate size (e.g., panel-level process), the challenge of advanced fabrication process inevitably increases. To this end, the higher etching performance and lower operating temperature provided by the substrate processing equipment 100 in accordance with the instant disclosure allows it to replace traditional polishing process in many applications, thereby avoiding the problem of chip damage. Meanwhile, the use of high-density free radicals generated there-by may also increase etching rate, thereby ensuring improved productivity and yield.

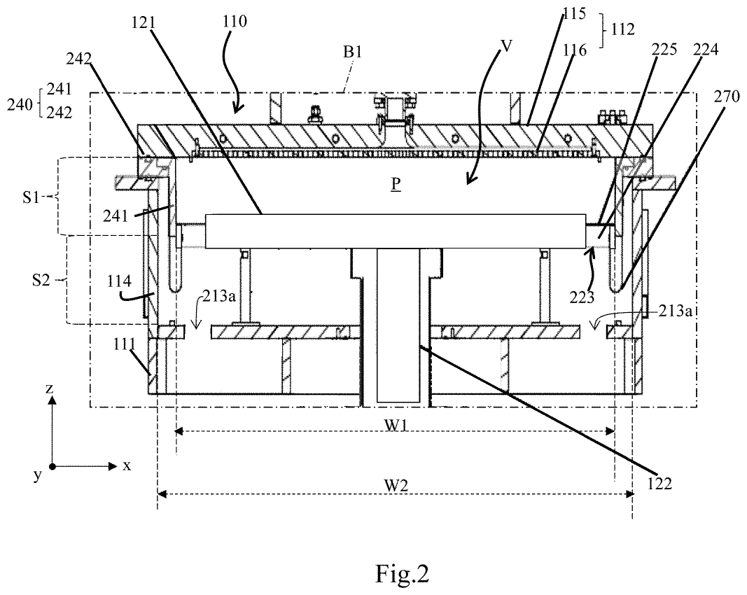

FIG. 2 shows an enlarged regional view of a substrate processing equipment according to some embodiments of the present disclosure. For simplicity and clarity of description, some details/sub-components of the exemplary system are not marked/shown in this figure. In some embodiments, FIG. 2 may represent a partial enlarged view as indicated by the dashed box B1 as shown in FIG. 1.

In some embodiments, the baffle ring 240 of the substrate processing equipment generally comprises two portions: a partition wall 241 and a flange 242. As shown in the figure, the flange 242 extends generally transversely (for example, along the x-y plane) and is arranged to situate between the base 111 and the plasma inlet wall 112. In the illustrated embodiment, the laterally extending surface of the flange provides a closing/sealing interface between the baffle ring 240 and the chamber body 110. The partition wall 241 extends substantially in a longitudinal direction (for example, along the z direction), and is arranged to be seated between the lateral inner chamber wall 114 of the base 111 and the substrate carrier 120. In the illustrated embodiment, a gap is maintained between the downward-extending partition wall 241 and the inner chamber surface of the chamber body 110. As a whole, the inner surface of the chamber wall 114 and the inward-facing lateral surface of the retaining ring 240 respectively form the lateral surrounding wall at different height segments in the process chamber 110 (e.g., as shown by sections S1 and S2 in the figure). The inner surface of the aforementioned surrounding wall defines an inner space V, which has two or more width segments (e.g., respectively denoted as W1 and W2). For example, in the schematic cross-sectional view of the exemplary chamber 110, the surrounding wall (which is cooperatively defined by the lateral wall 114 and the retaining ring 240) is formed with a first section S1 and a second section S2 with unequal widths. In the illustrated embodiment, the first section S1, which is relatively close to the plasma inlet wall 112, is provided with an inner diameter (i.e., the separation denoted as the first width W1) that is marginally larger than the overall width of the substrate carrier 120 to allow the entrance/passage of the substrate stage into the volume that corresponds to the first section S1. In some embodiments, the upper chamber region that corresponds to the first section S1 forms a processing region P for the substrate carrier 120, while the wider lower subspace corresponding to the second section S2 forms a loading region of the inner space V.

In some embodiments, the surrounding wall around section S1 is provided with a circumferentially continuous arrangement to substantially prevent easy passage/leaking of processing gas and/or plasma out of the processing region P (through the gap between the baffle ring 240 and the edge of the substrate carrier 120). When the substrate stage 120 is moved into the process region P (e.g., in the position shown in FIG. 2), radicals from the RPS (e.g., through the plasma distribution component 116) may be substantially confined in the process region P. In this way, processing gas and/or plasma may be kept from flowing into the lower subspace under the substrate stage 120, thereby maintaining processing gas and/or plasma in the process region P. In the illustrated embodiment, the baffle ring 240 continuously surrounds the outer periphery of the substrate stage 120 to form a narrow gap there-with, thus substantially blocking processing gas and/or plasma from passing into the lower region of the inner space V. In some embodiments, the height (e.g., in the z-direction) of the first section S1 is not less than 200 mm. With this arrangement, the height of the process region P (i.e., the distance between the substrate support surface and the spray head 116) may reach at least 200 mm. In the illustrated embodiment, the inner diameter W1 is approximately maintained at a predetermined constant value within the range of the first section S1. In the schematic cross-sectional view of the exemplary process chamber 110, the length of an inner surface of the partition wall 241 of the retaining ring 240 (as a part of the inner surface of the surrounding wall) defines the first section S1 (e.g., z direction), and is set to be greater than 200 mm (e.g., 220 mm).

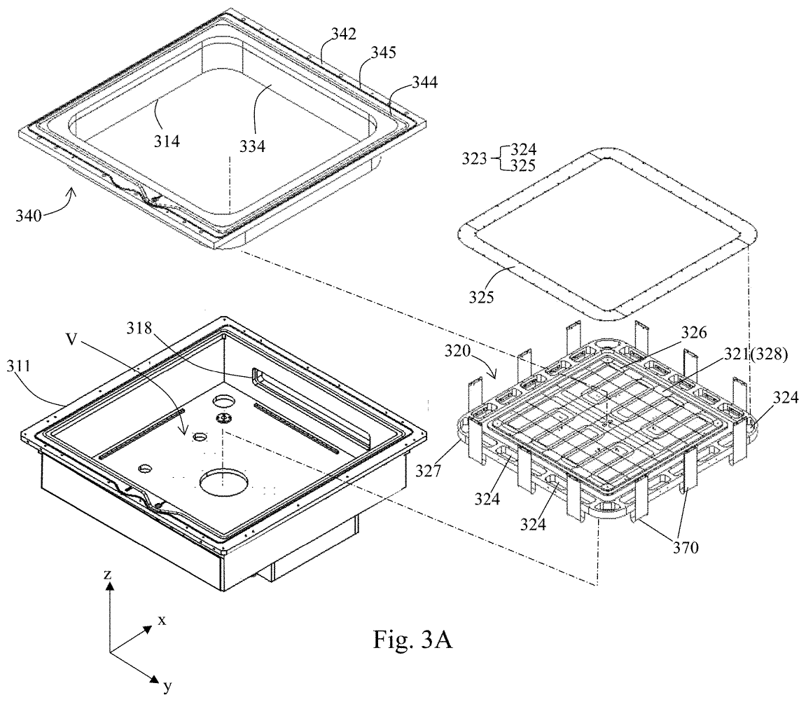

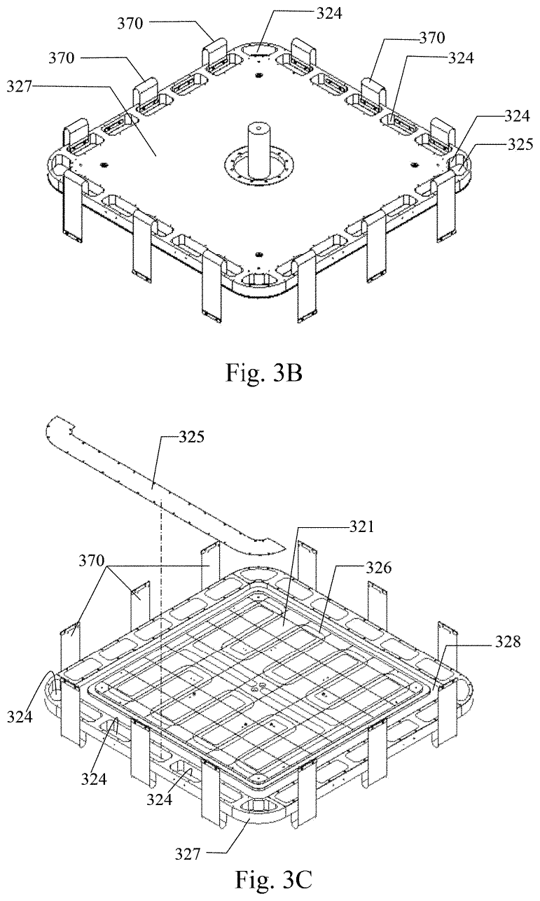

In some embodiments, the entrance and exit (e.g., port 318 of FIG. 3A) for the substrate to be moved out or into the process chamber is provided in the lower section of the chamber (e.g., second section S2). When the substrate carrier 120 is lowered to the segment that corresponds to the second section S2, the loading/unloading operation of a workpiece (e.g., substrates) may be performed. The inner diameter W2 of the second section S2 is larger than the inner diameter W1 of the first section S1. Such inner width arrangement helps to facilitate easy loading/unloading operation for the substrate carrier 120. In the illustrated embodiment, the difference in the inner diameters of the sidewalls in the chamber body is formed by the incorporation of a separate baffle ring 240 having a different (narrower) inner diameter. In other embodiments, the inner width differential between the first and the second sections may be realized through an integral structure in the chamber side wall.

In some embodiments, the substrate carrier 120 is further provided with a fluid channel structure at the edge region thereof. The fluid channel structure (e.g., exhaust passage 223 as shown in instant figure and FIG. 3B, 3C) includes perforated plate member 224/324 and exhaust port 225/325 formed in the edge region of the stage 120 (to be arranged under the perforated plate 224/324). When exhaust equipment (not shown in the figure) is activated, byproducts in the processing region P may be extracted to the space below the substrate stage 120 (corresponding to the second section S2) through the exhaust passage 223. The ports in the perforated plate 224 may be substantially evenly distributed in predetermined patterns, so as to allow byproducts to evenly flow into the subspace below the processing region P (under the stage 120). In some embodiments, the aperture of the perforated plate is in a range from about 0.5 to 5 mm (e.g., 1 mm).

In the illustrated embodiment in FIG. 2, the process chamber 110 further includes exhaust ports 213a. By-products can be exhausted from the chamber through the ports 213a. The exhaust ports 213a are arranged adjacent to two opposite sides of the process chamber 110, respectively. In the illustrated embodiment, the exhaust ports 213a are arranged under the perforated plate 225 and projectively overlapped with the perforated plate 224. In some embodiments, the diameter of the pumping channel (for example, the pumping port 213a) is substantially in the range of 25 mm to 150 mm.

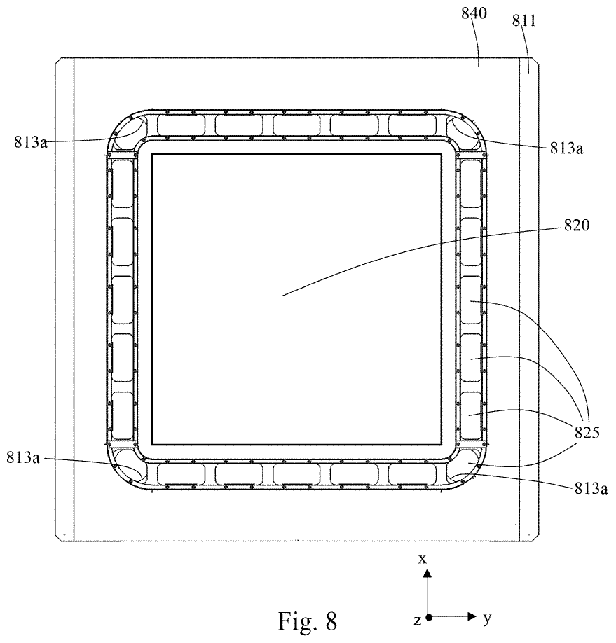

Please refer to FIG. 8, the number and location of the exhaust/pumping ports may affect/be utilized to optimize the uniformity of gas exhaustion. For example, in the embodiment shown in FIG. 8 (in which the aforementioned perforated plate is omitted for clarity of illustration), the exemplary process chamber 811 is provided with a baffle ring 840, and substrate carrier 820 is disposed within the retaining ring 840. The illustrated process chamber 811 is provided with four pumping ports 813a, which are arranged to overlap the four exhaust ports 824 at the corners of the substrate stage 820. Such a symmetrical arrangement may help to enhance uniformity of gas exhaustion.

In the placement of the carrier, if the edge of the substrate carrier (e.g, carrier 120) is too close to the surrounding surface of the first section S1 (e.g, the inward-facing surface 241 of the baffle ring 240), during the elevator movement of the substrate stage 120, the outer edge of stage 120 may rub against the inner surface of the first section S1 of the annular wall. Such friction may shorten the life of the equipment, and may also produce particles that pollute the internal environment of the process chamber. In some embodiments, a gap of a proper width is reserved between the inner surface of the first section S1 (for example, the inner surface of the retaining ring 241) and the outer periphery of the substrate stage 120. In some embodiments, a width of the gap is in a ranged from about 0.2 to 0.8 mm (e.g., 0.8 mm).

In some embodiments, a ratio between the aperture diameter of the perforated plate and the width of the stage edge gap is in the range of about 0.6 to 25. However, if the gap is substantially larger than the aperture of the perforation, undesirable leaking of processing gas/free radicals may become pronounced, which may again cause uneven distribution of the reaction gas. In addition, the impact of operating temperature on the hardware during device operation also needs to be taken in design considerations. For example, while the gap width between the hardware structures depends on the precision of modern machining (which can be kept fairly small), if the gap dimension is too small (for example, less than 0.8 mm), the gap may be compromised due to thermal expansion of the tool components caused by the elevated temperature during operation. For example, in some processes under high temperature conditions, thermal expansion of the substrate stage 120 may inevitably occur. As a result, the outer edge of the stage 120 may extends to reach the inner surface of the first section S1. It has been found that a gap width design proximate the aperture size of the perforated plate helps to maintain uniform distribution of processing gas over the substrate stage 120. For instance, in some embodiments, the gap width between the stage and the baffling ring is arranged to be substantially equal to the width of an aperture in the perforated plate. In some embodiments, a ratio between the aperture diameter of the perforated plate and the width of the stage edge gap is in the range of about 0.7 to 1.3, for example, 1.25. Meanwhile, the incorporation of a corresponding heat sink/dissipating mechanism on the substrate carrier to keep substrate temperature in check (e.g., below 140 degrees Celsius) also helps to ensure fabrication quality and maintain the normal operation of the processing equipment.

On the other hand, the RF return path of the plasma generating device may be interrupted due to the aforementioned stage edge gap. In some embodiments, the substrate stage 120 may be electrically coupled to the process chamber 110 through one or more flexible conductive members (for example, pliable member 270) to establish an RF return path. For example, in the illustrated embodiment, one end of the flexible conductive member 270 is electrically connected to the first section S1 of the surrounding wall, and the other end is connected to the substrate stage 120. In some embodiments, the substrate stage 120 is electrically coupled to the baffle ring 240 through a plurality of flexible conductive members 270. In some embodiments, the placement of the flexible conductive member 270 may offset the outer periphery of the substrate stage 120 and the inner surface of the retaining ring 240. In the illustrated embodiment, the partition wall 241 of the baffle ring 240 is structurally separated from the chamber side wall 114. Meanwhile, one end of the flexible conductive member 270 is fixed the partition wall 241 at a location facing the chamber sidewall 114 (e.g., through a fixing member, such as a screw). The other end of the flexible member 270 is fixed at the location of the exhaust port 225 situated at the periphery region of the substrate stage 120. The flexible conductive member 270 is provided with a length sufficient to maintain a state of physical contact with the substrate stage 120 during the elevator movement. For instance, when the substrate stage 120 is in the position shown in the figure, the flexible conductive member 270 is hung between the sidewall 114 and the substrate stage 120 in a suspended manner.

The flexible conductive member 270 may be a strip, wire, or cable that provides an RF conductive medium. In some embodiments, the flexible conductive member 270 may be implemented as a flexible strip made of a conductive material, or a flexible strip with conductive coating. In some embodiments, the material of the flexible conductive member may be metal, such as copper. In some embodiments, the flexible conductive member may include a composite structure, for example, a heterogeneous material structure, such as silver plated over a pliant copper strip. In some embodiments, the thickness of the flexible conductive member is not greater than 1 mm (e.g., less than 0.6 mm). In some embodiments, the thickness of the flexible conductive member is about 0.2 mm. The flexible conductive member 270 can ensure continuous electrical coupling between the processing chamber and the RF power source. The return path arrangement for the RF current may be determined based on the electrical properties (e.g., conductivity/impedance) and placement of the flexible conductive member 270. In addition, the positions or separation distance between the flexible conductive members 270 may be further tuned to modify the uniformity of electrical field, thereby increasing the uniformity of gas/plasma distribution and process stability.

FIG. 3A shows a three-dimensional schematic diagram of a substrate processing equipment according to some embodiments of the present disclosure. For simplicity and clarity of illustration, some details/subcomponents of the exemplary system are not explicitly labeled/shown in this figure, for example, the plasma inlet wall and the remote plasma source are omitted from instant view. FIGS. 3B and 3C respectively shows a three-dimensional schematic diagram of a substrate support according to some embodiments of the present disclosure.

The exemplary base 311 substantially resumes the shape of a rectangular trough, which has a generally planar bottom plate and four chamber side walls that cooperatively defines an internal space V for accommodating a substrate carrier (e.g., stage 320). In some embodiments, one of the four side walls of the base 311 is provided with a load port 318 to enable access of the substrate into/out of the internal space V. The chamber side wall is further provided with a valve configured to close load port 318. Prior to a thinning process or plasma treatment (such as etching, cleaning, surface activation), the substrate stage 320 may be moved to a corresponding position (e.g., corresponding to the second section S2 shown in FIG. 2), and the chamber load port valve may be opened for the substrate to enter the internal space V, so as to allow secure placement of the substrate on the substrate supporting surface 321 of the substrate stage 320.

In the illustrated embodiment, the exemplary substrate supporting surface 321 has a substantially rectangular planar profile. For instance, the substrate stage 320 in the figure is configured to resume a rectangle profile with rounded corners. The illustrated substrate processing equipment is configured to perform plasma treatment on large size, panel level substrates. The substrate may include metal, dielectric insulating material, photoresist, silicon wafer, glass, and other composite materials. The illustrated equipment may handle rectangular substrates of different sizes, such as substrates with a side length in a range from about 200 to 650 mm.

In some embodiments, the substrate stage 320 includes channel arrangement 323 configured to allow passage of the processing gas/free radicals (e.g., for gas extraction). In some embodiments, the channel arrangement (e.g., exhaust channel) 323 is arranged along the periphery region of the substrate stage 320, and has strip-shaped elements that form an encircling pattern. The channel arrangement 323 includes a plurality of exhaust ports 324 arranged along the edge regions of the substrate stage 320, and are configured to enable fluid communication between the two opposite surfaces of the substrate supporting surface 321. The channel arrangement 323 further includes a perforated plate 325 disposed over the exhaust ports 324.

The perforated plate 325 is configured to cover the exhaust ports 324, and is arranged in a manner facing the plasma inlet wall (e.g., the plasma inlet wall 112 shown in FIG. 1). The perforated plate 325 is provided with a plurality of substantially uniformly distributed apertures. In some embodiments, a width of the aperture of the perforated plate is in a range from about 0.5 to 5 mm (e.g., 1 mm). In some embodiments, the exhaust passages 323 are distributed substantially symmetrically about the geometric center of the substrate stage 320. In some embodiments, the exhaust ports 324 may be equidistantly distributed along two opposite sides or all four sides of the substrate stage 320. The symmetrical arrangement of the exhaust channels 323 may contribute to the uniformity of free radical/processing gas distribution. In the illustrated embodiment, the exhaust ports 324 are not only distributed along the four sides of the substrate stage 320, but also formed at the four respective corner regions of the substrate stage 320. That is, the exhaust channels 323 are distributed along the entire periphery of the edge region of the substrate stage 320 and surround the substrate supporting surface 321. Such arrangement may help to further maintain the uniformity of gas exhaustion and reduce the phenomenon of free radicals/processing gas gathering at the corner regions of the pedestal.

In the embodiment illustrated in FIG. 3A, the four sides of the substrate stage 320 are provided with flexible conductive members 370, so that the potential distribution in the processing chamber may be more uniform. In some embodiments, the placement of the flexible conductive member 370 avoids the front/load port side of the substrate carrier 320 (i.e., the side closest to the load ports 318 in the x direction). Such arrangement enables easier loading and/or unloading operations of the substrate. In the embodiment illustrated in FIG. 3C, the rear side opposite to the front side is also kept free from the placement of flexible conductive member, in order to preserve symmetry and uniformity of the inner chamber potential distribution.

In the embodiment illustrated in FIG. 3C, the substrate stage 320 is further provided with a fluid channel structure 326 having serpentine routing and embedded under the substrate supporting surface 321. The fluid channel structure 326 is configured to receive fluid (water or other cooling medium) from a coolant source to adjust the temperature condition of the substrate over the substrate supporting surface 321. For example, when performing a thinning process on the illustrated equipment, the etching rate of the substrate may be substantially proportional to the substrate temperature. The fluid channel structure 321 of the substrate stage 320 may be used to maintain workpiece temperature (e.g., substrate) below about 140° C. In other operating scenarios, such as a photoresist ashing process, the temperature state of a substrate may be maintained in a range of, e.g., between 250 and 300° C.

In the embodiment illustrated in FIG. 3C, the substrate stage 320 further includes a support plate 327, which is arranged substantially parallel to the spray head 116, and is configured to for elevator movement (i.e., travel along the z axis). The peripheral area of the support plate 327 forms the exhaust port array (ports 324). The aforementioned plurality of flexible conductive members 370 are fixed at the respective locations of the encircling array of exhaust ports 324. In some embodiments, the support plate 327 includes a conductive material, such as copper. A carrier plate 328 is disposed at the center of the supporting plate 327 to form the substrate supporting surface 321 and the fluid channel structure 326. In some embodiments, the stage is further provided with a positioning ring (or cover ring) arranged around the substrate supporting surface 321 and is located between the substrate supporting surface 121 and the exhaust ports 324. In some embodiments, the positioning ring comprises an insulating material, such as Al₂O₃, ZrO₂, Si₃N₄, AlN, machinable ceramics, Quartz, glass, or Teflon. When the lifting plate 327 moves along the z-axis, the substrate supporting surface 321, the exhaust channel 323, and the flexible conductive member 370 will move synchronously there-with.

The exemplary baffle ring 340 includes a generally annular structural profile that defines a substantially continuous inner surface 343 in the circumferential direction (e.g., along the inner periphery). The planar profile of the inner surface 343 substantially resumes a rectangular shape with rounded corners. In some embodiments, the baffle ring 340 includes a conductive material, such as aluminum. The top surface of the flange 342 of the baffle ring 340 is further provided with a sealing member (for example, a sealing ring 344) for maintaining air tightness of the process chamber upon closure. The top surface of the flange 342 of the baffle ring 340 may also be provided with an electromagnetic interference (EMI) shielding element (such as a conductive gasket 345). Likewise, sealing members and EMI shielding elements may be selectively provided on the contact interface between the chamber base 311 and the flange 342. In the illustrated embodiment, the base is electrically connected to the lid via the baffle ring, so that the base, the baffle ring and the lid share equal potential. The encircling partition wall 341 shown in the figure is formed from the assembly of a plurality of components in a sealed manner. Such composite arrangement helps to ease hardware manufacture complexity, e.g., when fabricating the rounded profiles at the corners.

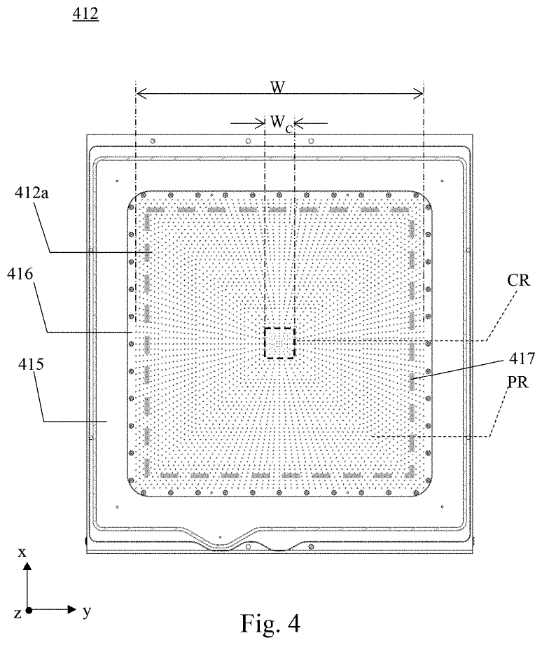

FIG. 4 shows a schematic bottom view of a plasma intake wall according to some embodiments of the present disclosure. For simplicity and clarity of description, some details/sub-components of the exemplary system are not explicitly marked/shown in this figure. In some embodiments, FIG. 4 is a planar view along the section line IV-IV parallel to FIG. 1.

The plasma intake wall 412 shown in FIG. 4 comprises a lid 415 and a distribution member 416. The distribution member 416 has a substantially rectangular shape with rounded corners. In some embodiments, the plasma distribution component 416 and the cover 415 may be made of conductive materials (such as aluminum) and be in electrical communication with each other. The plasma intake wall 412 has a flow distribution aperture pattern 412a configured to face toward the substrate stage (for example, the substrate stage 120 of FIG. 1) in the chamber. The overall layout of the flow distribution pattern 412a presents a substantially rectangular profile. In the illustrated embodiment, the distribution pattern 412a is made up with a plurality layer of rectangular ring-shaped aperture arrays (e.g., the array indicated by the dotted line 417), distributed in a substantially concentric manner. The aperture array in a concentric rectangular layout facilitates the uniform flow of processing gas/free radicals over a substantially rectangular workpiece (e.g., a panel level substrate). In some embodiments, in each ring of the rectangular aperture array, a distance between adjacent holes (in the circumferential direction) is in a range of about 10 to 25 mm. In some embodiments, the distance is in a range of about 10.5 to 21.3 mm. The regular circumferential spacing may contribute to the uniformity of free radical distribution. In some embodiments, a diameter of the distribution aperture is not greater than 2 mm (e.g., such as 1.8 mm). The dispensing angle/outlet direction of the distribution hole may be set to be parallel to the direction of the elevator movement of the substrate stage (for example, in the Z direction).

In some embodiments, the distribution pattern 412a has a central area CR in the distribution hole pattern. The central region CR is configured to alleviate ultraviolet light exposure from a remote plasma source toward a process workpiece (e.g., substrate). The provision of the central region CR may also restrict free radicals from directly reaching and etching the substrate. For example, in some embodiments, a size of the apertures in the central region CR is smaller than that of the apertures in the surrounding peripheral region PR, so as to reduce the direct ultraviolet light exposure to the substrate. In some embodiments, the width of the aperture in the central region CR may be less than about 1 mm, such as 0.8 mm. In some embodiments, the width of the hole in the peripheral area PR may be greater than about 1.5 mm, such as 1.8 mm. In some embodiments, the aperture density in the central region CR is lower than the density of holes in the peripheral region. In some embodiments, the dispensing direction/outlet angle of the aperture in the central region CR may be arranged offset the elevatory direction (e.g., the z direction) of the substrate stage (e.g., in a tilted manner). In some embodiments, the central area CR presents a substantially rectangular layout. In some embodiments, the pattern width We may account for about 8 to 10% of the total pattern width W of the plasma distribution member 416. The ratio of the central pattern area to the overall pattern coverage calls for mindful design considerations. If the central area C is too large, it may hinder the uniform distribution of processing gas; if the ratio is too small, it may provide insufficient ultraviolet blockage for the substrate, which may result in the insufficient reduction of regional etch rate (e.g., in the region of the substrate that projectively overlaps with the central region CR). In some embodiments, a ratio between the overall pattern coverage to the central pattern size is in a range of about 60:1 to 120:1.

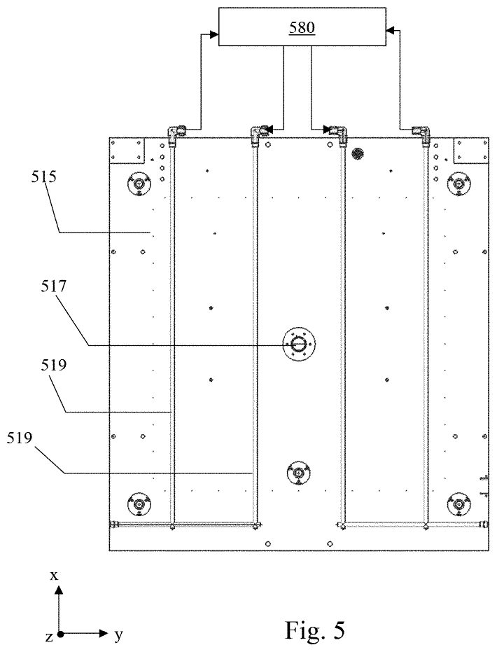

FIG. 5 shows a schematic cross-sectional view of a plasma intake wall according to some embodiments of the present disclosure. For simplicity and clarity of description, some details/sub-components of the exemplary system are not explicitly marked/shown in this figure. In some embodiments, FIG. 5 represents a cross-sectional view along the section line V-V in FIG. 1.

The cover 515 on the plasma intake wall shown in FIG. 5 is provided with an inlet port 517 configured to receive processing gas/free radicals from a remote plasma source. In some embodiments, the inlet port 517 is provided in the central region of the cover 515. In some embodiments, the central area (e.g., corresponds to the central area CR of FIG. 4) of the flow distribution pattern (such as the aperture pattern 412a shown in FIG. 4) projectively overlaps the inlet port 517, thus providing blockage against the direct ultraviolet input from a RPS. In some embodiments, the projection of the inlet port 517 (e.g., on x-y plane) falls within the aforementioned central region CR. In some embodiments, the inlet defines a first geometric planar profile; the central region defines has a second geometric planar profile, and the first geometric plane profile is substantially different from the first geometric plane profile. In some embodiments, the inlet 517 presents a substantially circular planar profile, while the central region CR has a substantially rectangular planar profile.

In some embodiments, the cover 515 of the plasma inlet wall is further provided with a flow runner/channel network (e.g., channel pattern 519) that offsets the central region thereof. The flow channel 519 is configured to establish fluidic communicate with a fluid source 580. In some operating scenarios, when the temperature state of the cover 515 is not high enough (e.g., lower than 30 Celsius degree), process byproducts (e.g., CxHyOz,CxFy) may condense on the cover 515 and/or the spray head (e.g., component 116 as shown in FIG. 1). The generation of such condensation may hinder chamber maintenance efforts, and may also affect longevity of the hardware components. By controlling the temperature setting of the fluid source 580, the temperature state of the cover 515 and/or the shower head may be adjusted to prevent such condensation, thereby ensuring surface characteristics of the cover 515 and/or the spray head. For example, in a thinning process, proper temperature setting of the fluid source 580 (e.g., maintaining temperature state of the cover 515 at about 30 to 100 Celsius degree) may help reducing condensation of byproducts over the internal hardware. The fluid runners shown in the figure can be formed by drilling. In other embodiments, the flow channel 519 in the cover 515 may be formed by computerized numerical control (CNC) techniques.

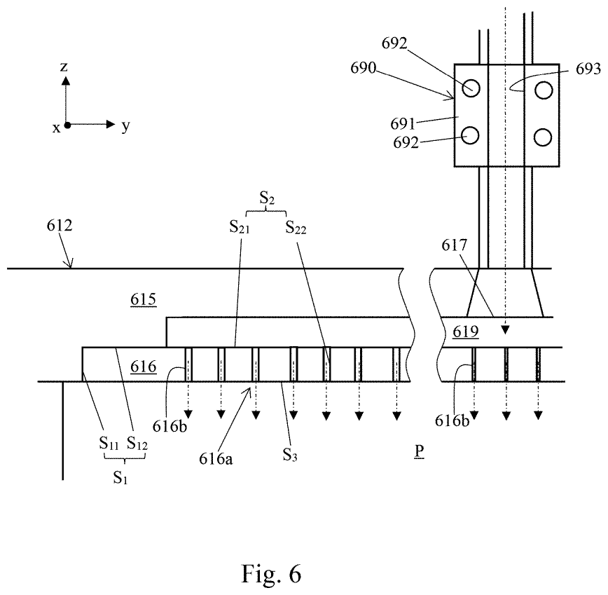

FIG. 6 shows a schematic regional cross-sectional view of a plasma intake wall according to some embodiments of the present disclosure. For simplicity and clarity of description, some details/subcomponents of the exemplary system are not explicitly marked or shown in this figure.

The plasma inlet wall 612 has a hollow structure that defines a plasma distribution volume 619, which is in fluid communication with the inlet 617 and the distribution aperture array 616b. The output from the remote plasma source (not shown in the figure) may enter the plasma distribution volume 619 through the inlet 617, and then enter the processing region P for the substrate carrier (e.g., stage 120 as shown in FIG. 1) through the distribution aperture 616b. In some embodiments, the structural design of the top and/or bottom aperture side wall profile S22 of the aperture 616b may be further tuned to minimize flow turbulence. In some embodiments, the side wall profile of the aperture is provided with chamfer profile.

In some embodiments, the device further includes a valve module 690, which is arranged between the remote plasma source (upstream of the valve 690, not shown in the figure) and the inlet 617. The valve module 690 is configured to regulate fluid communication from the RPS to the processing region P. In some operating scenarios, the substrate loading and/or unloading process may disrupt the vacuum condition established in the processing region P. If the remote plasma source is kept in full fluid connection with the process chamber, it may be susceptible to frequent pressure fluctuations and thus suffer reduction of service life. The provision of valve 690 allow blockage of the fluid communication between processing region in the chamber and the remote plasma source, thus may help to prolong the service life of the remote plasma source. In some embodiments, the valve body 691 of the valve module 690 comprises a metal material, such as aluminum or stainless steel (for example, Steel Special Use Stainless, SUS). In some embodiments, stainless steel valve body is used for its competitive cost and material strength. However, the use of SUS valve bodies may increase recombination rate of fluorine based radicals after dissociation. Such recombination reaction (exothermic reaction) may raise temperature of the valve body. However, because heat transfer coefficient of SUS material is not comparable to that of aluminum material, the SUS valve body may more likely be prone to worn out due to elevated temperature conditions. In some embodiments, in order to reduce the recombination of the dissociated fluorine radicals over surface of the SUS valve body, the surface of the valve body and/or the connecting pipe exposed to the free radical environment (such as the inner surface 693) may be provided with surface coating (e.g., with a layer Teflon (PTFE)). Such arrangement may help to alleviate the recombination of dissociated fluorine free radicals and the erosion of the fluorine free radicals on the valve body. In some embodiments, the valve body and the pipe are made of aluminum alloy with surface treatment (e.g., anodizing) that helps to reduce recombination of free radicals (e.g., fluorine). In some embodiments, the aluminum valve body may be used to help reduce the recombination rate of fluorine radicals. In some embodiments, the valve module is further provided with a cooling structure. The cooling structure may include a fluid channel 692 embedded in the valve body 691. The flow channel 692 is configured to receive coolant from a fluid source. In some embodiments, the cooling structure may be further provided with a thermoelectric cooling chip. In some embodiments, the surface of the pipeline or the valve body exposed to the free radicals (e.g., the inner surface 693) may be provided with an oxide layer (e.g., anodizing) to enhance erosion resistance against free radicals. In some embodiments, the valve body may comprise a ball-valve or gate-valve type vacuum valve member configured to regulate fluid flow rate.

In the illustrated embodiment, the plasma intake wall 612 includes a cover 615 and a plasma distribution member 616. The cover 615 is configured to establish sealing closure of the process chamber. In the illustrated embodiment, a shower head (for example, the plasma distribution member 616) is detachably installed on the cover 615. The plasma distribution member 616 is formed with a distribution aperture pattern 616a arranged in the flow path of reaction gas (from the RPS), and is designed to uniformly guide the RPS output toward the surface of the substrate. The plasma distribution part 616 may be disposed between the inlet port 617 and the substrate stage. For instance, in the illustrated embodiment, the plasma distribution component 616 is arranged on one side of the inlet port 617 (facing the inside of the plasma distribution space 619) and facing the substrate stage (e.g., the substrate stage 120). In the illustrated embodiment, the plasma distribution member 616 has a width narrower than the process region P, so that the boundary between the plasma distribution member 616 and the cover 615 (e.g., the side surface S₁₁ of the shower head) falls within the projection of the process region P. In some embodiments, the shower head 616 may be configured to be wider than the process area P, so that the boundary between the shower head 616 and the cover 615 recites outside the workpiece carrying area over the substrate stage. This arrangement may reduce the impact from the micro particles generated between hardware components (e.g., fastening members that join the shower projection 616 and the cover 615). In the illustrated embodiment, the plasma intake wall 612 adopts a two-piece design (i.e., having structurally separated plasma distribution member 616 and the cover 615). In other embodiments, the plasma distribution component and the cover may be fabricated as a unitary integral structure.

In some embodiments, the surface of the shower head (such as the plasma distribution member 616) may be provided with an oxide layer to inhibit the recombination of adjacent free radicals, so as to maintain the activity of the free radicals. However, oxide layer generally has a large surface resistance, which is not conducive to building a radio frequency loop. In some embodiments, the interface S₁ between the plasma distribution member 616 and the cover 615 is formed with a surface resistance value lower than that of the surface area S₂ of the plasma distribution member 616 (e.g., the area that exposes to the plasma distribution volume). This design may establish a radio frequency loop through the shower head, the cover, the surrounding wall (such as the retaining ring), the flexible conductive member, the substrate carrier, and the RF electrode. The illustrated interface S1 comprises a side surface portion S₁₁ and a top surface portion S₁₂. In some embodiments, the surface area S₂ of the plasma distribution member 616 exposed to the plasma distribution space 619 comprises: 1) area S₂₁ on the top surface of the plasma distribution part 616 (area not in contact with the cover 615) and 2) area S₂₂ that defines the sidewall of the distribution aperture 616b. In some embodiments, the surface resistance value of the surface area S₃ of the plasma distribution component 616 (area facing the substrate stage) is also provided with lower surface resistance than that of the surface area S₂. This arrangement is conducive to the establishment of the radio frequency loop.

In some embodiments, the shower head 616 is made of conductive material, such as metal. In some embodiments, the shower head 616 may be fabricated from aluminum plate. In some methods of manufacturing shower heads, the aluminum plate is first anodized, so an oxide layer is formed over the surface of the aluminum plate. Subsequently, selective surface treatment may be performed over the aluminum plate. For instance, the oxide layer over the entire bottom surface (such as surface area S₃), the side surfaces (such as surface area S₁₁), and the peripheral portion of the top surface (such as surface area S₁₂) of the aluminum plate may be processed, so that surface resistance value over the aforementioned regions is reduced (lower than surface area S₂₁). The process may involve oxide layer reduction/removal treatment on the bottom surface, the side surface, and the periphery of the top surface, through technique such as etching or polishing. In some embodiments, it can be observed that the bottom surface (e.g., surface area S₃) and side surfaces (e.g., surface area S₁₁) of shower head 616 are formed with metallic luster. In some embodiments, the peripheral portion (e.g., surface area S₁₂) of the top surface of the shower head 616 is formed with metallic luster. In some embodiments, the part of the shower head surrounded by the peripheral portion (for example, the surface area S₂₁) is formed with a relatively darker color, such as earth color.

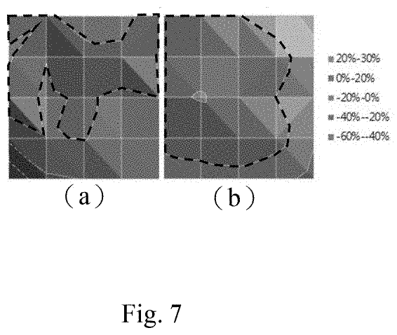

FIG. 7 shows experimental data according to some embodiments of the present disclosure. The left hand picture (a) shows the result of an etching process using a shower head without surface treatment. The right hand picture (b) shows a result of an etching process using a shower head with the aforementioned surface treatment (e.g., shower head 616 in FIG. 6). The 4×4 grid blocks shown on the left (a) and right (b) correspond to the locations of an etched surface over a rectangular substrate. Each grid block is filled with different gray scale shadings to show the etching rate measured from the experiment. The percentage range shown on the right hand side of FIG. 7 represents the percentage range obtained relative to a reference etching rate (in um/min), and is expressed in a manner corresponding to different gray scale levels. It can be observed from the data that compared to a shower head without surface treatment, the use of a shower head provided with different surface characteristics (e.g., shower head 616 in FIG. 6) may significantly improve the etch uniformity over the substrate surface. For example, the dotted lines in the pictures encircles the area with a relatively small etch rate difference/ratio (0-20%, where etch rate is more uniform). As can be seen from the figure, the dotted frame on the right picture (b) encircles a larger area. It is found that the use of the shower head in accordance with the instant disclosure (e.g., the spray head 616 in FIG. 6) may increase the uniformity of the substrate surface etch rate by more than 15% (e.g., by 16.7%).

One aspect of the present disclosure discloses a substrate processing equipment, which includes a processing chamber and a substrate carrier. The processing chamber has a plasma inlet wall and a surrounding wall. The plasma inlet wall is configured to receive outputs from a remote plasma source. The surrounding wall has an inner surface, and the inner surface defines an inner space for receiving a substrate. The substrate carrier is elevatably arranged in the inner space of the process chamber, and comprises a substrate supporting surface facing the plasma inlet wall. In a cross section of the process chamber, the surrounding wall defines a first section and a second section along the substrate carrier's direction of elevation. The first section corresponds to a process area of the substrate carrier and defines a first width of separation. The second section is farther away from the plasma inlet wall than the first section, and defines a width greater than the first width.

In some embodiments, the substrate support includes gas passage having stripe planar profile. The gas passage is formed with: a plurality of exhaust ports disposed along an outer edge of the substrate support configured to enable fluid communication between opposite sides of the substrate supporting surface, and a perforated plate facing the plasma intake wall and arranged over the exhaust ports, the perforated plate having plurality of substantially evenly distributed holes.

In some embodiments, when the substrate support is in the processing region, a gap is formed between the outer edge of the substrate support and the first segment of the surrounding wall. A width of a hole of the perforated plate is substantially equal to a width of the gap.

In some embodiments, the substrate support is electrically coupled to the first segment of the surrounding wall through a plurality of (substantially even distributed) pliant conductive members.

In some embodiments, the first segment is formed with a baffle ring arranged between the processing chamber and the substrate support, the baffle ring having an inner surface that makes up a part of the inner surface of the surrounding wall.

In some embodiments, the plasma intake wall is provided with a dispensing hole pattern having a substantially rectangular planar profile arranged toward the substrate support.

In some embodiments, the plasma intake wall comprises an inlet port having a first geometric planner profile, configured to receive output from the remote plasma source. A central region of the dispensing hole pattern protectively overlaps the inlet port, the central region has a second geometric planner profile. The first geometric planner profile is different from the second geometric planner profile.

In some embodiments, holes in the central region of the dispensing hole pattern is provided with a smaller size than holes in a periphery region that surrounds the central region.

In some embodiments, the plasma intake wall has a hollow body defining a plasma distributing volume. The dispensing hole pattern is formed on a plasma distributing member arranged on one side of the intake port that faces the substrate support. A surface area of the plasma distributing member that exposes to the plasma distributing volume has surface resistance value larger than that of a surface area of the plasma distributing member facing the substrate support.

In some embodiments, the plasma intake wall comprises a lid configured to establish a sealing engagement of the processing chamber. The plasma distributing member is detachably mounted on the lid. An interface between the plasma distributing member and the lid is provided with surface resistance smaller than that of the surface area of the plasma distributing member that exposes to the plasma distributing volume.

Another aspect of the present disclosure discloses a substrate processing equipment, which includes a processing chamber and a substrate carrier. The processing chamber defines an internal space to receive a substrate. The process chamber includes a base, a plasma inlet wall and a baffle ring. The plasma inlet wall is configured to seal the processing chamber base and to receive output from a remote plasma source. The baffle ring is arranged between the base and the plasma inlet wall. The substrate carrier is elevatably arranged in the inner space of the process chamber and has a substrate supporting surface facing the plasma inlet wall. In a cross-section of the process chamber, the width of a processing area for the substrate carrier defined by the inner surface of the baffle ring is narrower than an inner separation width of the base.

In some embodiments, the substrate support includes exhaust gas passage arranged to surround the substrate supporting surface and configured to move with the substrate supporting surface concurrently. The exhaust gas passage is formed with: a plurality of exhaust ports disposed along an outer edge of the substrate support that enable fluid communication between two opposite sides of the substrate supporting surface, and a perforated plate facing the plasma intake wall and arranged over the exhaust ports, the perforated plate has plurality of substantially evenly distributed holes.

In some embodiments, when the substrate support is in the processing region, a gap is formed between the outer edge of the substrate support and the baffle ring. A width of a hole of the perforated plate is substantially equal to a width of the gap.

In some embodiments, the substrate support is electrically coupled to the baffle ring through a plurality of (substantially even distributed) pliant conductive members.

In some embodiments, the plasma intake wall is provided with a dispensing hole pattern having a substantially rectangular planar profile arranged toward the substrate support.

In some embodiments, the plasma intake wall comprises an inlet port configured to receive output from the remote plasma source. Holes in a central region of the dispensing hole pattern protectively overlaps the inlet port are provided with a size smaller than holes in a periphery region that surrounds the central region.

In some embodiments, the central region has a substantially rectangular planner profile. The inlet port has a substantially circular planner profile.

In some embodiments, the plasma intake wall has a hollow body defining a plasma distributing volume. The dispensing hole pattern is formed on a plasma distributing member arranged on one side of the intake port that faces the substrate support. A surface area of the plasma distributing member that exposes to the plasma distributing volume has surface resistance value larger than that of a surface area of the plasma distributing member facing the substrate support.

In some embodiments, the plasma intake wall comprises a lid configured to establish a sealing engagement of the processing chamber. The plasma distributing member is detachably mounted on the lid. An interface between the plasma distributing member and the lid is provided with surface resistance smaller than that of the surface area of the plasma distributing member that exposes to the plasma distributing volume.

In some embodiments, the intake port is arranged at a central region of the lid. The lid of the plasma intake wall is further provided with fluid channels that evades the intake port.

The embodiments shown and described above are only examples. Therefore, many such details are neither shown nor described. Even though numerous characteristics and advantages of the present technology have been set forth in the foregoing description, together with details of the structure and function, the disclosure is illustrative only, and changes may be made in the detail, especially in matters of shape, size, and arrangement of the parts within the principles, up to and including the full extent established by the broad general meaning of the terms used in the claims. It will therefore be appreciated that the embodiments described above may be modified within the scope of the claims.

What is claimed is:

1. A substrate processing apparatus, comprising:
a processing chamber having
a plasma intake wall configured to receive output from a remote plasma source (RPS), and
a surrounding wall having inner surface defining an interior volume for receiving a substrate; and
a substrate support having a substrate supporting surface facing the plasma intake wall and elevatably arranged in the interior volume of the processing chamber;
wherein the surrounding wall, in a cross-section of the processing chamber, includes:
a first segment having a first width associated with a processing region for the substrate support, and
a second segment having a width greater than the first width that is further away from the plasma intake wall than the first segment.

2. The apparatus of claim 1,
wherein the substrate support includes gas passage having stripe planar profile,
wherein the gas passage is formed with:
a plurality of exhaust ports disposed along an outer edge of the substrate support configured to enable fluid communication between opposite sides of the substrate supporting surface, and
a perforated plate facing the plasma intake wall and arranged over the exhaust ports, the perforated plate having plurality of substantially evenly distributed holes.

3. The apparatus of claim 2,
wherein when the substrate support is in the processing region, a gap is formed between the outer edge of the substrate support and the first segment of the surrounding wall,
wherein a width of a hole of the perforated plate is substantially equal to a width of the gap.

4. The apparatus of claim 1,
wherein the substrate support is electrically coupled to the first segment of the surrounding wall through a plurality of pliant conductive members.

5. The apparatus of claim 1,
wherein the first segment is formed with a baffle ring arranged between the processing chamber and the substrate support, the baffle ring having an inner surface that makes up a part of the inner surface of the surrounding wall.

6. The apparatus of claim 1,
wherein the plasma intake wall is provided with a dispensing hole pattern having a substantially rectangular planar profile arranged toward the substrate support.

7. The apparatus of claim 6,
wherein the plasma intake wall comprises an inlet port having a first geometric planner profile, configured to receive output from the remote plasma source;
wherein a central region of the dispensing hole pattern protectively overlaps the inlet port, the central region has a second geometric planner profile;
wherein the first geometric planner profile is different from the second geometric planner profile.

8. The apparatus of claim 7,
wherein holes in the central region of the dispensing hole pattern is provided with a smaller size than holes in a periphery region that surrounds the central region.

9. The apparatus of claim 6,
wherein the plasma intake wall has a hollow body defining a plasma distributing volume;
wherein the dispensing hole pattern is formed on a plasma distributing member arranged on one side of the intake port that faces the substrate support;
wherein a surface area of the plasma distributing member that exposes to the plasma distributing volume has surface resistance value larger than that of a surface area of the plasma distributing member facing the substrate support.

10. The apparatus of claim 9,
wherein the plasma intake wall comprises a lid configured to establish a sealing engagement of the processing chamber;
wherein the plasma distributing member is detachably mounted on the lid;
wherein an interface between the plasma distributing member and the lid is provided with surface resistance smaller than that of the surface area of the plasma distributing member that exposes to the plasma distributing volume.

11. A substrate processing apparatus, comprising:
a processing chamber defining an interior volume for receiving a substrate, comprising
a base,
a plasma intake wall configured to seal the base and receive plasma from a remote plasma source, and
a baffle ring arranged between the base and the plasma intake wall; and
a substrate support having a substrate supporting surface facing the plasma intake wall and elevatably arranged in the interior volume of the processing chamber,
wherein in a cross-section of the processing chamber, an inner surface of the baffle ring defines a processing region for the substrate support has a width narrower than that of the base.

12. The apparatus of claim 11,
wherein the substrate support includes exhaust gas passage arranged to surround the substrate supporting surface and configured to move with the substrate supporting surface concurrently,
wherein the exhaust gas passage is formed with:
a plurality of exhaust ports disposed along an outer edge of the substrate support that enable fluid communication between two opposite sides of the substrate supporting surface, and
a perforated plate facing the plasma intake wall and arranged over the exhaust ports, the perforated plate has plurality of substantially evenly distributed holes.

13. The apparatus of claim 12,
wherein when the substrate support is in the processing region, a gap is formed between the outer edge of the substrate support and the baffle ring,
wherein a width of a hole of the perforated plate is substantially equal to a width of the gap.

14. The apparatus of claim 11,
wherein the substrate support is electrically coupled to the baffle ring through a plurality of pliant conductive members.

15. The apparatus of claim 11,
wherein the plasma intake wall is provided with a dispensing hole pattern having a substantially rectangular planar profile arranged toward the substrate support.

16. The apparatus of claim 15,
wherein the plasma intake wall comprises an inlet port configured to receive output from the remote plasma source;
wherein holes in a central region of the dispensing hole pattern protectively overlaps the inlet port are provided with a width narrower than holes in a periphery region that surrounds the central region.

17. The apparatus of claim 16,
wherein the central region has a substantially rectangular planner profile;
wherein the inlet port has a substantially circular planner profile.

18. The apparatus of claim 17,
wherein the plasma intake wall has a hollow body defining a plasma distributing volume;
wherein the dispensing hole pattern is formed on a plasma distributing member arranged on one side of the intake port that faces the substrate support;
wherein a surface area of the plasma distributing member that exposes to the plasma distributing volume has surface resistance value larger than that of a surface area of the plasma distributing member facing the substrate support.

19. The apparatus of claim 18,
wherein the plasma intake wall comprises a lid configured to establish a sealing engagement of the processing chamber;
wherein the plasma distributing member is detachably mounted on the lid;
wherein an interface between the plasma distributing member and the lid is provided with surface resistance smaller than that of the surface area of the plasma distributing member that exposes to the plasma distributing volume.

20. The apparatus of claim 19,
wherein the intake port is arranged at a central region of the lid;
wherein the lid of the plasma intake wall is further provided with fluid channels that evades the intake port.
